(19) United States
(12) Patent Application Publication
(10) Pub. No.: US 2010/0252795 A1
(43) Pub. Date: Oct. 7, 2010

(54) Phase change memory device

(75) Inventors: Yoon Jong Song, Seoul (KR); Dong Won Lim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/754,839

(22) Filed: Apr. 6, 2010

(30) Foreign Application Priority Data
Apr. 7, 2009 (KR) 10-2009-0030003

(51) Int. Cl. H01L 45/00

(52) U.S. Cl. 257/2; 257/E45.001

(57) ABSTRACT

Provided is a phase change memory device and a method of manufacturing the phase change memory device. In the phase change memory device, since a flat surface of a buffer pattern and a lower electrode are stably in contact with each other in a center of a recess, a resistance of a contact surface between the lower electrode and the buffer pattern can be minimized and thereby the phase change memory device can be operated by a small current. Since a method of manufacturing the phase change memory device needs one time etching process to form a recess exposing a semiconductor substrate to an insulating layer until forming a lower electrode after forming a device isolation layer, it is very economical.

### CROSS-REFERENCE TO RELATED APPLICATIONS

This U.S. non-provisional patent application claims priority under 35 U.S.C. §119 of Korean Patent Application No. 10-2009-0030003, filed on Apr. 7, 2009, the entire contents of which are hereby incorporated by reference.

### BACKGROUND OF THE INVENTIVE CONCEPT

The present disclosure herein relates to nonvolatile memory devices and methods of manufacturing the same, and more particularly, to a phase change memory device and a method of manufacturing the same.

Nonvolatile memory devices retain their stored data even when their power supplies are interrupted. Nonvolatile memory devices mainly adopt flash memory cells having a stacked gate structure. The stacked gate structure can include a tunnel oxide layer, a floating gate, an inter-gate dielectric layer and a control gate electrode that are sequentially stacked on a channel. The quality of the tunnel oxide layer and the coupling ratio of the cell can be increased to improve reliability of the flash memory cells.

Phase change memory devices have been introduced instead of the flash memory devices. The phase change memory devices can perform a program operation and a read operation using a difference of a resistance in accordance with a phase change of a phase change pattern.

### Summary of the Inventive Concept

Embodiments of the inventive concept provide a phase change memory device. The phase change memory device may include an interlayer insulating layer including a recess exposing a semiconductor substrate; a semiconductor layer and an ohmic layer sequentially stacked in the recess; a buffer pattern having a sidewall which is in contact with a top surface of the ohmic layer and is aligned with a sidewall of the semiconductor layer; a lower electrode which is in contact with a portion of the buffer pattern in a center of the recess and has an upper portion higher than an upper portion of the buffer pattern; a phase change pattern which is in contact with a portion of the upper portion of the lower electrode; and an upper electrode on the phase change pattern.

The phase change memory device may further include a spacer pattern interposed between an inner side surface of the buffer pattern and an outer side surface of the lower electrode.

The buffer pattern may have a lower electric resistance than that of the lower electrode.

The phase change memory device may further include a buried insulating pattern which is in contact with an inner bottom surface and an inner side surface of the lower electrode.

The phase change memory device may further include an impurity implantation line which is formed on the semiconductor substrate and is in contact with the semiconductor layer.

Embodiments of the inventive concept also provide a method of manufacturing a phase change memory device. The method may include forming a recess exposing a semiconductor substrate by forming an interlayer insulating layer on the semiconductor substrate and then patterning the interlayer insulating layer; forming a semiconductor layer to fill a portion of the recess; forming an ohmic layer so that the ohmic layer is in contact with a top surface of the semiconductor layer in the recess; forming a buffer pattern having a sidewall aligned with a sidewall of the semiconductor layer in the recess; forming a lower electrode which is in contact with the buffer pattern in a center of the recess and has an upper portion higher than an upper portion of the buffer pattern; and forming a phase change pattern which is in contact with an upper portion of the lower electrode and an upper electrode which is in contact with the phase change pattern.

The forming of the buffer pattern may include: conformally forming a buffer layer on an entire surface of the semiconductor substrate on which the ohmic layer is fowled; forming a sacrificial layer on the buffer layer to fill the recess; exposing the buffer layer on the interlayer insulating layer and leaving a sacrificial layer pattern in the recess by planarizing the sacrificial layer; selectively removing the buffer layer on the interlayer insulating layer and the buffer layer of an upper portion of the recess; and selectively removing the sacrificial layer pattern.

The forming of the lower electrode may include: conformally forming a lower electrode layer on an entire surface of the semiconductor substrate on which the buffer pattern is formed; forming a buried insulating layer on the lower electrode layer to fill the recess; and planarizing the buried insulating layer and the lower electrode layer on the interlayer insulating layer to form a lower electrode and a reclaim insulating pattern in the recess.

The forming of the lower electrode may include: conformally forming a spacer layer on an entire surface of the semiconductor substrate on which the buffer pattern is formed; performing an anisotropic etched back process on the spacer layer to remove the spacer layer on the interlayer insulating layer and to form a spacer exposing a center portion of the buffer pattern in the recess; conformally forming a lower electrode layer on the semiconductor substrate on which the spacer is formed; forming a buried insulating layer on the lower electrode layer to fill the recess; and planarizing the buried insulating layer, the lower electrode layer, the spacer layer and the interlayer insulating layer to form a spacer pattern, a lower electrode having an inside diameter smaller than an inside diameter of the recess and a buried insulating pattern.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the figures:

FIG. 1 is a cross-sectional view of a phase change memory device in accordance with an embodiment of the inventive concept;

FIGS. 2 through 12 are cross-sectional views illustrating a process of manufacturing the phase change memory device illustrated in FIG. 1;

FIG. 13 is a top plan view of FIG. 12;

FIG. 14 is a top plan view of a phase change memory device in accordance with another embodiment of the inventive concept;

FIG. 15A is a cross-sectional view taken along the line I-I′ of FIG. 14 according to another embodiment;

FIG. 15B is a cross-sectional view taken along the line II-II′ of FIG. 14 according to another embodiment;

FIGS. 16 and 17 are cross-sectional views which sequentially illustrate a process of manufacturing the phase change memory device of FIG, 15A.

FIG. 18A is a cross-sectional view taken along the line I-I′ of FIG. 14 according to still another embodiment;

FIG. 18B is a cross-sectional view taken along the line II-II′ of FIG. 14 according to still another embodiment; and

FIG. 19 is a block diagram of a memory system illustrating an application example of a phase change memory device in accordance with embodiments of the inventive concept.

### DETAILED DESCRIPTION OF THE EMBODIMENTS

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims.

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

### <First Embodiment>

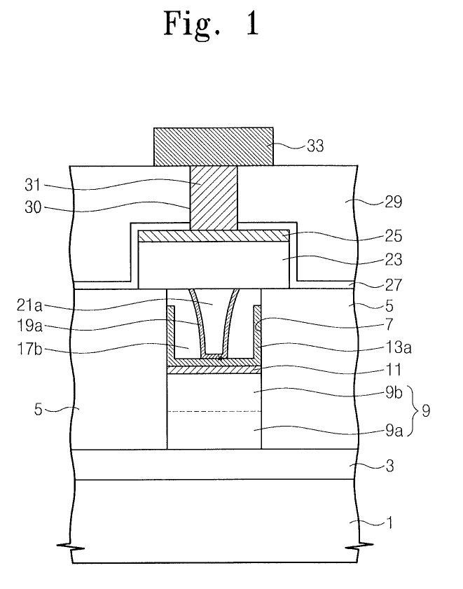

FIG. 1 is a cross-sectional view of a phase change memory device in accordance with an embodiment of the inventive concept.

Referring to FIG. 1, an impurity implantation line 3 is disposed in an active region defined by a device isolation layer (not illustrated) in a semiconductor substrate 1. The impurity implantation line 3 is a region of a line shape that an impurity is implanted in the semiconductor substrate 1 and can perform an interconnection function like a word line., The impurity implantation line 3 is illustrated in the present embodiment but a pattern type formed of a doped polysilicon or a metal contained layer may be used for an interconnection function. An interlayer insulating layer 5 including a recess 7 is disposed on the semiconductor substrate 1. A portion of the recess 7 is filled with a semiconductor layer 9. The semiconductor layer 9 may include a first semiconductor layer 9a and a second semiconductor layer 9b. The first and second semiconductor layers 9a and 9b may be doped with an impurity of a different type from each other. The impurity implantation line 3 may be doped with an impurity of the same type as the first semiconductor layer 9a. In this case, the first semiconductor layer 9a and the second semiconductor layer 9b may constitute a diode. The first and second semiconductor layers 9a and 9b may be doped with an impurity of the same type. In this case, the impurity implantation line 3 is doped with an impurity of a different type from the semiconductor layer 9 and thereby the semiconductor layer 9 and the impurity implantation line 3 may constitute a diode. As an illustration, the first semiconductor layer 9a and the impurity implantation line 3 may be doped with an N-type impurity and the second semiconductor layer 9b may be doped with a P-type impurity.

An ohmic layer 11 having a sidewall aligned with a sidewall of the semiconductor layer 9 is disposed in the recess 7. The ohmic layer 11 may, for example, be a metal silicide. A buffer pattern 13a may be disposed on the ohmic layer 11. The buffer pattern 13a is in contact with a top surface of the ohmic layer 11 and has a sidewall aligned with a sidewall of the semiconductor layer 9 in the recess 7. An upper portion of the buffer pattern 13a is lower than a top surface of the interlayer insulating layer 5. It is illustrated in FIG. 1 that the buffer pattern 13a has a cup shape, but the buffer pattern 13a may have a disc shape without a vertically protruding portion from an edge of a bottom surface which is in contact with the ohmic layer 11. A lower electrode 19a is disposed on the buffer pattern 13a and the lower electrode 19a is in contact with a portion of the buffer pattern in the center of the recess 7. An upper portion of the lower electrode 19a has the same height as an upper portion of the interlayer insulating layer 5 and may have a cup shape. The lower electrode 19a may be formed of material having an electric resistance greater than the buffer pattern 13a. For example, the lower electrode 19a may be formed of a titanium nitride layer having a high nitrogen content and the buffer pattern 13a may be formed of a titanium nitride layer having a high titanium content. Thus, since the lower electrode 19a which is in contact with a phase change pattern 23 which will be described later has a great electric resistance, heat is generated in end portion of the lower electrode 19a during a program operation and thereby a partial phase change of the phase change pattern is performed. Also, since the lower electrode 19a is stably in contact with a flat portion of the buffer pattern 13a, a contact resistance between the buffer pattern 13a and the lower electrode 19a is reduced and thereby an operation current, for example, a reset current can be lowered when an erasure operation. The ohmic layer 11 can perform an ohmic layer function between the semiconductor layer 9 and the buffer pattern 13a and/or can perform a function of a cell diode electrode of the semiconductor layer 9. The buffer pattern 13a can perform an ohmic layer function between the lower electrode 19a and the ohmic layer 11.

A spacer pattern 17b is interposed between an outer surface of the lower electrode 19a and an inner surface of the buffer pattern 13a. The spacer pattern 17b may, for example, be formed of a silicon nitride layer and has a flat top surface of the same height as the interlayer insulating layer 5. An inner side surface and an inner bottom surface of the lower electrode 19a having a cup shape is covered with a buried insulating pattern 21 a. That is, an inner space formed by the lower electrode 19a of a cup shape is filled with a buried insulating pattern 21a.

A phase change pattern 23 which is partially in contact with an upper portion of the lower electrode 19a and an upper electrode 25 which is in contact with the phase change pattern 23 are sequentially disposed. A capping layer 27 covers a side surface of the phase change pattern 23 and a top surface and a side surface of the upper electrode 25 and an upper interlayer insulating layer 29 is disposed on the capping layer 27. An upper electrode contact 31 which is in contact with the upper electrode 25 by penetrating the upper interlayer insulating layer 29 and the capping layer 27 and an upper electrode interconnection 33 is disposed on the upper electrode contact 31.

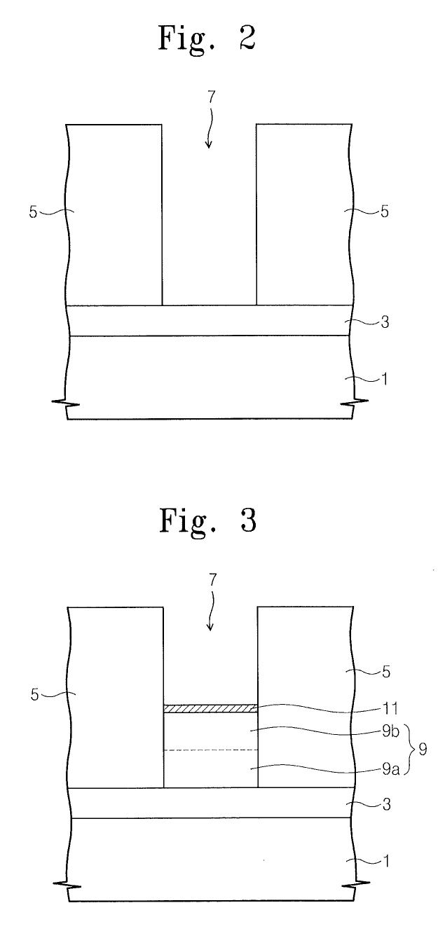

FIGS. 2 through 12 are cross-sectional views illustrating a process of manufacturing the phase change memory device illustrated in FIG. 1.

Referring to FIG. 2, a device isolation layer (not illustrated) is formed in a semiconductor substrate 1 to define an active region. The device isolation layer may be formed by a shallow trench isolation (STI) process. An ion implantation process is performed on the active region to form an impurity implantation line 3 of a line shape. Before or after forming the device isolation layer on the semiconductor substrate 1, an impurity of an opposite type to the impurity implantation line 3 is doped to form a well. An interlayer insulating layer 5 is formed on the semiconductor substrate 1. The interlayer insulating layer 5 may be formed of a single insulating layer. A photolithography process is performed on the interlayer insulating layer 5 to form a photoresist pattern and the interlayer insulating layer 5 is patterned using the photoresist pattern as an etching mask to form a recess 7 exposing a predetermined region of the impurity implantation line 3.

Referring to FIG. 3, a semiconductor layer 9 is formed in the recess 7. The semiconductor layer 9 may be formed by a selective epitaxial growth technique using the semiconductor substrate 1 of the impurity implantation line 3 exposed by the recess 7 as a seed layer. Thus, the semiconductor layer 9 may be formed to have a crystal structure aligned with a crystal structure of the semiconductor substrate 1. A first semiconductor layer 9a and a second semiconductor layer 9b may be formed by doping the semiconductor layer 9 with an impurity using an in-situ doping while growing the semiconductor layer 9 by a selective epitaxial growth technique. A growth of the semiconductor layer 9 stops when the semiconductor layer 9 reaches a wanted height in the recess 7 to form the semiconductor layer 9 illustrated in FIG. 3. The semiconductor layer 9 may be grown so as to completely fill the recess 7 and subsequently a selective etching process is performed to control a height of the semiconductor layer 9 in the recess 7. The semiconductor layer 9 may be formed to be an epitaxial semiconductor layer by a solid phase epitaxy (SPE) method, a metal-induced crystallization (MIC) method, a laser-induced epitaxial growth (LEG) method or a metal-induced lateral crystallization (MILC) method. In this case, a selective etching process lowering a height by partially removing the semiconductor layer 9 filling the recess land an ion implantation process forming the first and second semiconductor layers 9a and 9b by alternately doping the semiconductor layer 9 with an impurity of a different type are needed. After forming the semiconductor layer 9, an ohmic layer 11 is formed on the semiconductor layer 9. A metal layer is conformally formed on an entire surface of the semiconductor substrate 1 on which the semiconductor layer 9 is formed, and then an annealing process is performed on the metal layer. As a result, the metal layer on the semiconductor layer 9 is changed to metal silicide and thereby the ohmic layer 11 may be formed. The metal layer which is not changed to metal silicide is removed. The ohmic layer 11 may, for example, be formed of a cobalt silicide layer.

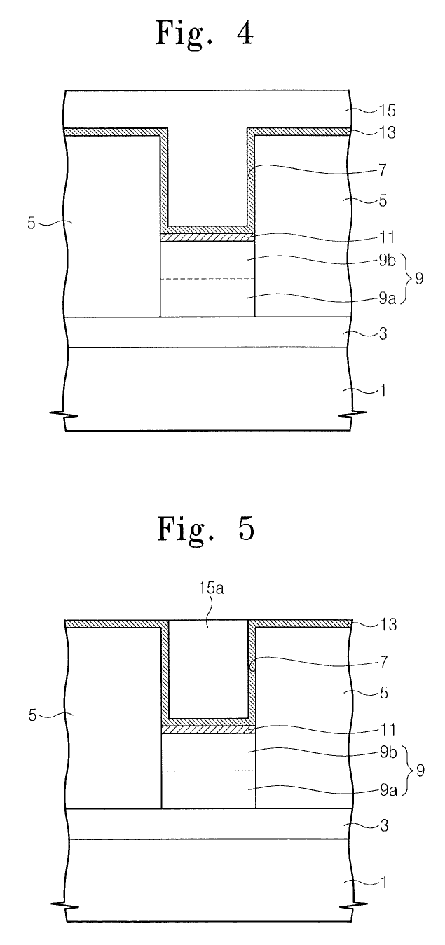

Referring to FIG. 4, a buffer layer 13 is conformally formed on an entire surface of the semiconductor substrate 1 on which the ohmic layer 11 is formed. A sacrificial layer 15 is formed on the buffer layer 13 to fill the recess 7. The buffer layer 13 may be formed by, for example, a metal organic chemical vapor deposition and may be formed of a titanium nitride layer having a high titanium content. The sacrificial layer 15 may be formed of material having an etching selectivity with respect to the buffer layer 13, for example, a silicon oxide layer, a silicon nitride layer, a silicon germanium, a silicon oxynitride layer or the like. The sacrificial layer 15 may be formed of material having a wet etching selectivity with respect to not only the buffer layer 13 but also the interlayer insulating layer 5.

Referring to FIG. 5, a planarization etching process is performed to remove the sacrificial layer 15 on the interlayer insulating layer 5, to expose the buffer layer 13 on the interlayer insulating layer 5 and to leave a sacrificial layer pattern 15a in the recess 7 at the same time. At this time, the buffer layer 13 may perform a function of an etch stop layer of the planarization etching process. An anisotropic dry etching process or a chemical mechanical polishing (CMP) may be used as the planarization etching process.

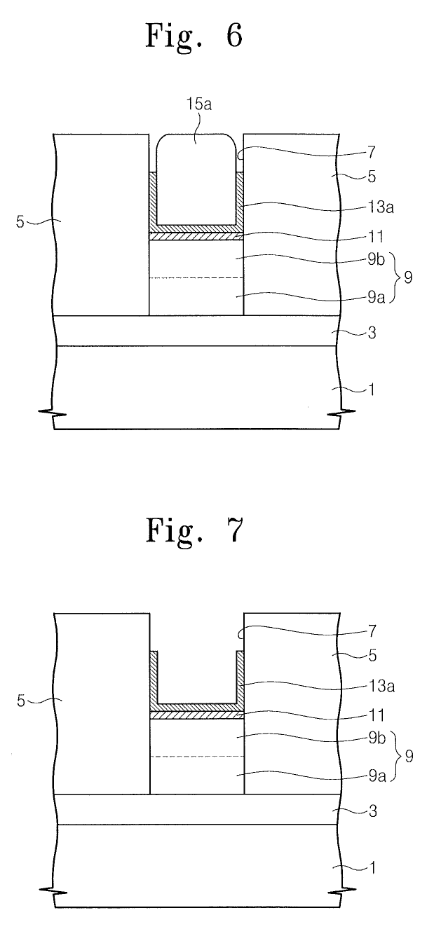

Referring to FIG. 6, a selective etching process is performed to remove the exposed buffer layer 13 on a top surface of the interlayer insulating layer 5 and further to remove a portion of an upper portion of the buffer layer 13 located in the recess 7. As a result, a top surface of the interlayer insulating layer 5 is exposed, an inner wall of an upper portion of the recess 7 is exposed and a buffer pattern 13a is formed in the recess 7. During the selective etching process, the sacrificial layer pattern 15a remains in the recess 7 to prevent an inner bottom surface of the buffer layer 13 from being damaged and to protect the inner bottom surface of the buffer layer 13.

Referring to FIG. 7, the sacrificial layer pattern 15a is selectively removed. If the sacrificial layer pattern 15a is material of a system of a silicon nitride layer, it may be removed by using phosphoric acid. If the sacrificial layer pattern 15a is tungsten or silicon germanium, it may be removed by using a mixture of ammonium hydroxide, hydrogen peroxide and water. Since the sacrificial layer pattern 13 a can be removed by a selective wet etching process, an etching damage does not occur on an inner bottom surface of the buffer pattern 13a.

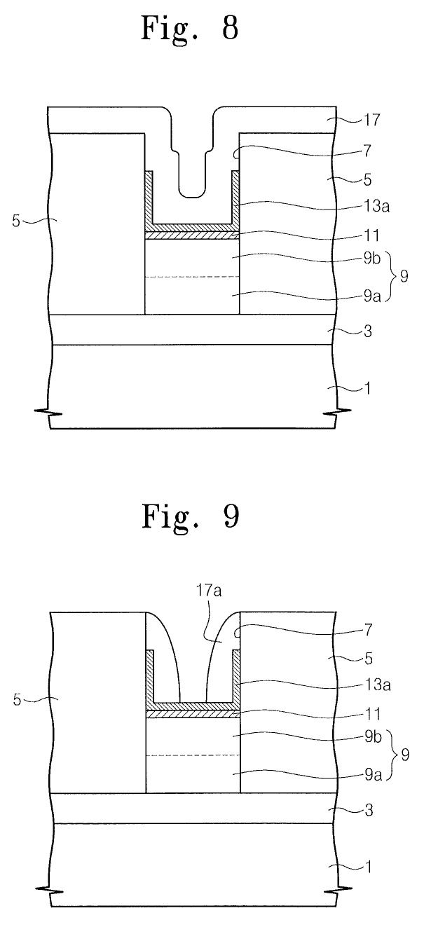

Referring to FIG. 8, a spacer layer 17 is conformally formed on the semiconductor substrate 1 on which the sacrificial layer pattern 15a is removed. The spacer layer 17 may be formed to have a thickness which does not completely fill the recess 7. The spacer layer 17 may be formed of, for example, a silicon nitride layer.

Referring to FIG. 9, an anisotropic dry etching process is performed on the spacer layer 17 to remove the spacer layer 17 on the interlayer insulating layer 5 and the spacer layer 17 in the center of the recess 17, thereby forming a spacer 17a covering a sidewall of the recess 7 and exposing the buffer pattern 13 a of the center of the recess 7.

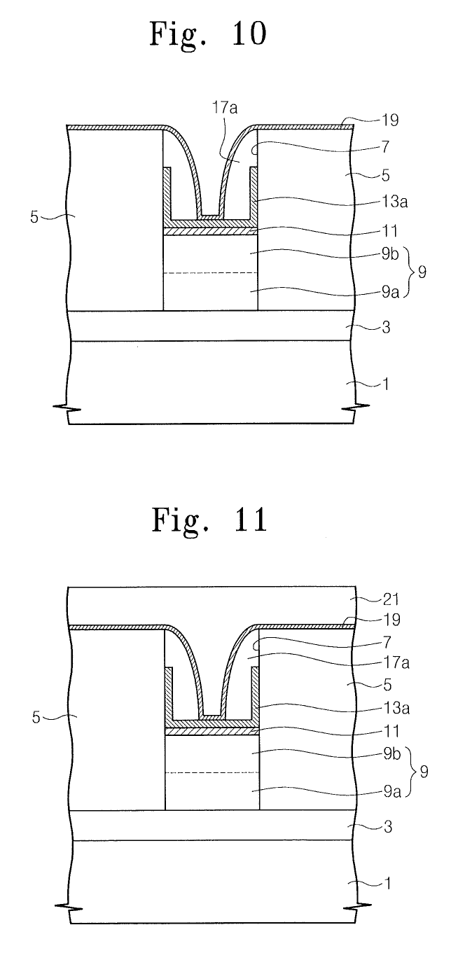

Referring to FIG. 10, a lower electrode layer 19 is conformally formed on an entire surface of the semiconductor substrate 1 on which the spacer 17a is formed. Thus, the lower electrode layer 19 is stably in contact with the buffer pattern 13a exposed by the spacer 17a on the center of the recess 7. The lower electrode layer 19 may be formed of a titanium nitride layer having a high nitrogen content by a metal-organic chemical vapor deposition (MOCVD).

Referring to FIG. 11, a buried insulating layer 21 is formed on an entire surface of the semiconductor substrate 1 on which the lower electrode layer 19 is formed to fill the recess 7. The buried insulating layer 21 may be formed of material of a system of a silicon oxide layer having a good step coverage characteristic.

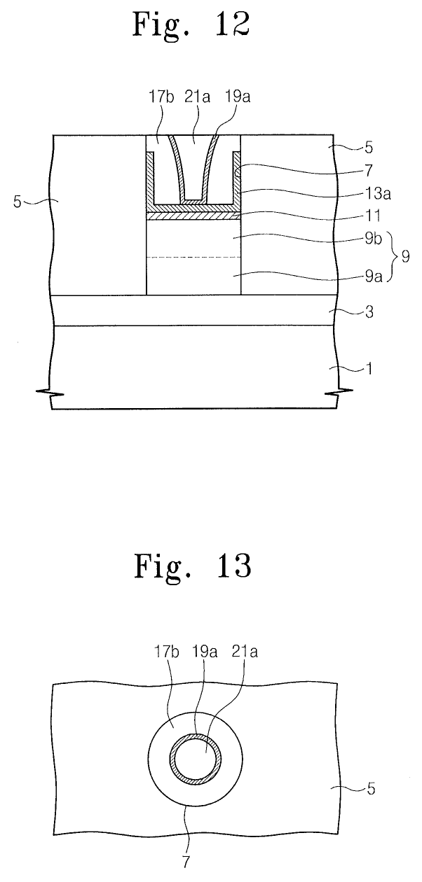

Referring to FIG. 12, a planarization etching process is performed to remove upper portions of the buried insulating layer 21, the lower electrode 19, the interlayer insulating layer 5 and the spacer 17a, thereby forming a lower electrode 19a, a buried insulating pattern 21 a and a spacer pattern 17b in the recess 7. The interlayer insulating layer 5, the lower electrode 19a, the buried insulating pattern 21a and the spacer pattern 17b are formed to have flat top surfaces of the same height by the planarization etching process. FIG. 13 is a top plan view of FIG. 12. An upper portion of the buffer pattern 13a is not exposed when viewed from FIG. 13. Thus, the lower electrode 19a may be formed to have a cup shape having the inside diameter smaller than the inside diameter of the recess 7.

Only one photolithography process for forming a photoresist pattern is performed from a process of forming the device isolation layer to a process of forming the lower electrode 19a. Thus, a photolithography process which needs a high cost can be minimized, thereby improving an economical efficiency.

Referring back to FIG. 1, a phase change material layer and an upper electrode layer are sequentially stacked on the semiconductor substrate 1 on which the lower electrode 19a and the buried insulating pattern 21a are formed, and then is patterned to form a phase change pattern 23 and an upper electrode 25 that are sequentially stacked. The phase change material layer may be formed of a chemical compound that at least one of Te and Se which are elements of chalcogenide system is combined with at least one of Ge, Sb, Bi, Pb, Sn, Ag, As, S, Si. P, O and C. The phase change pattern 23 may be in contact with all of the top surfaces of the lower electrode 19a. The phase change pattern 23 may be in contact with a portion of the top surfaces of the lower electrode 19a to lower a program current. With this view, in a patterning process for forming the phase change pattern 23, the patterning process may be performed so that the phase change pattern 23 is in contact with only a portion of the top surfaces of the lower electrode 19a. After recessing a portion of circumference of an upper portion of the lower electrode 19a, an insulating layer is filled. Subsequently, a capping layer 27 and an upper interlayer insulating layer 29 are conformally and sequentially stacked on an entire surface of the semiconductor substrate 1 on which the phase change pattern 23 and the upper electrode 25 are formed. The upper interlayer insulating layer 29 and the capping layer 27 are successively patterned to form an upper electrode contact recess 30 exposing the upper electrode 25. An upper electrode contact 31 is formed in the upper electrode contact recess 30. An upper electrode interconnection 33 running in a direction different from the impurity implantation line 3 is formed on the upper interlayer insulating layer 29.

### <Second Embodiment>

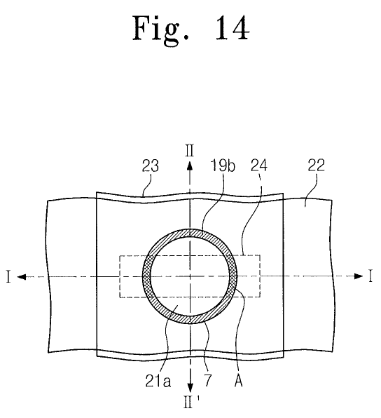

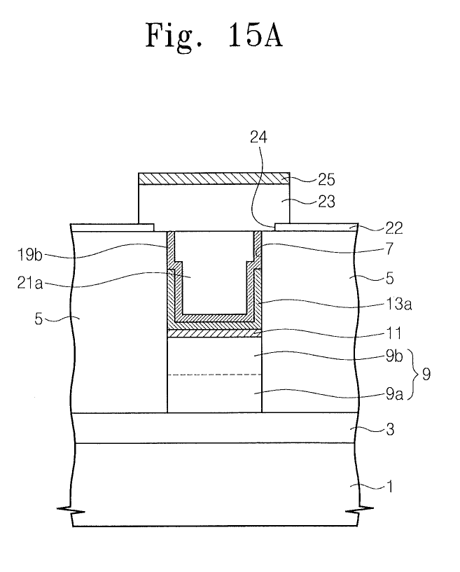

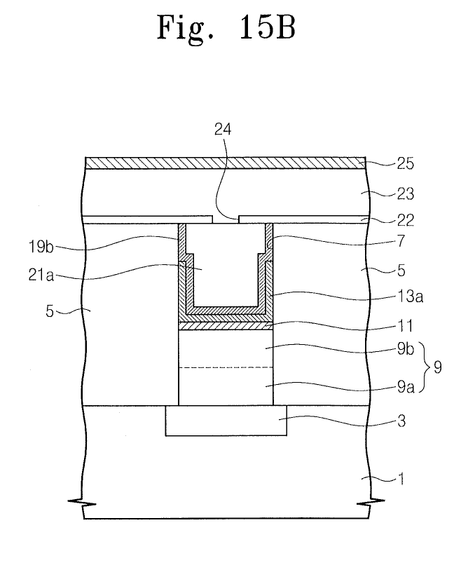

FIG. 14 is a top plan view of a phase change memory device in accordance with another embodiment of the inventive concept. FIG. 15A is a cross-sectional view taken along the line I-I′ of FIG. 14 according to another embodiment. FIG. 15B is a cross-sectional view taken along the line II-II′ of FIG. 14 according to another embodiment.

Referring to FIGS. 14, 15A and 15B, the phase change memory device in accordance with the present embodiment does not include the spacer pattern 17b illustrated in FIG. 1. That is, in the phase change memory device in accordance with the present embodiment, in a recess 7, a lower electrode 19b is formed to be in contact with a bottom surface and an inner side surface of a buffer pattern 13a and to cover a portion of an upper portion of a sidewall of the recess 7. Thus, a diameter of circumference of an upper portion of the lower electrode 19b is identical with an inside diameter of the recess 7. A total area of a top surface of the lower electrode 19b is greater than that of the first embodiment. Thus, if an entire top surface of the lower electrode 19b is in contact with a phase change pattern 23, a lot of program currents may be needed. To solve the problem, the phase change pattern 23 has a structure which is in contact with a portion of the top surface of the lower electrode 19b. With this view, an insulating layer 22 having a window 24 exposing only a portion of the top surface of the lower electrode 19b is disposed between the phase change pattern 23 and the lower electrode 19b. The phase change pattern 23 is in contact with the top surface of the lower electrode 19b exposed through the window 24. An area that the phase change pattern 23 and the lower electrode 19b are in contact with each other may be reduced by the insulating layer 22 including the window 24. The window 24 may have various shapes, for example, a round shape, a square, an oval, a rectangle or the like. An exposed location and an exposed portion of the top surface of the lower electrode 19b may be various. Other constructions may be identical with the first embodiment.

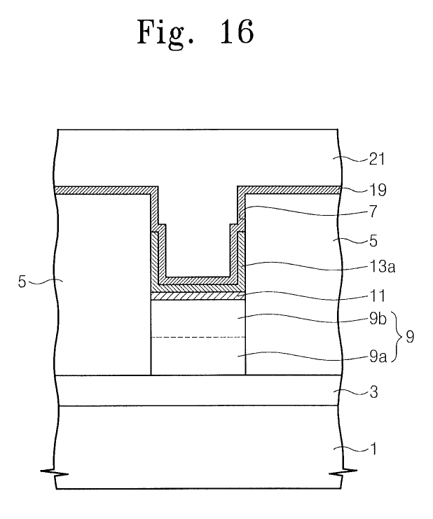

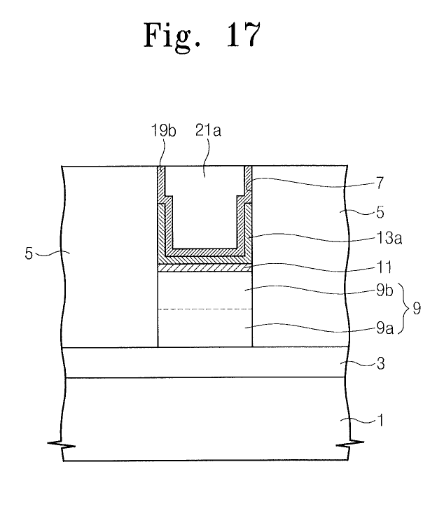

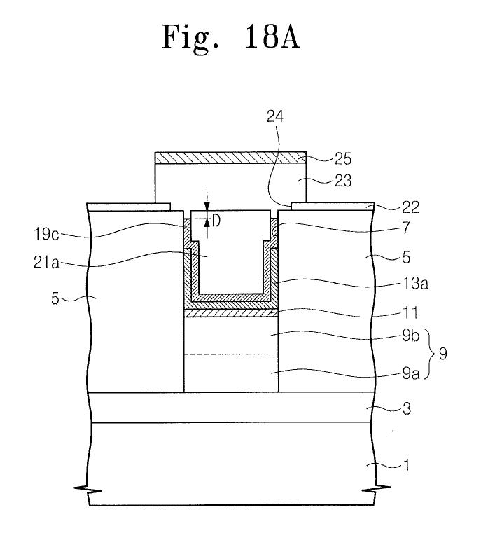

FIGS. 16 and 17 are cross-sectional views which sequentially illustrate a process of manufacturing the phase change memory device of FIG. 15A.

. Referring to FIG. 16, a lower electrode layer 19 is conformally formed on a semiconductor substrate 1 on which a buffer pattern 13a is formed. An area that the lower electrode layer 19 and the buffer pattern 13a are in contact with each other is greater than that of the first embodiment and thereby a contact resistance between the lower electrode layer 19 and the buffer pattern 13a may become more low. A buried insulating layer 21 is formed on the lower electrode layer 19 to fill the recess 7.

Referring to FIG. 17, a planarization etching process is performed to remove the buried insulating layer 21 and the lower electrode layer 19 on the interlayer insulating layer 5, thereby forming a lower electrode 19b and a buried insulating pattern 21a in the recess 7. In this case, the interlayer insulating layer 5 may be performed a function of a planarization etching stop layer.

Referring to FIG. 17, a planarization etching process is performed to remove the buried insulating layer 21 and the lower electrode layer 19, thereby forming a lower electrode 19b and a buried insulating pattern 21a in the recess 7. In this case, the interlayer insulating layer 5 may perform a function of a planarization etch stop layer.

Referring to FIGS. 14,15A and 15B, an insulating layer 22 is formed on an entire surface of the semiconductor substrate 1. The insulating layer 22 is patterned to form a window 24 exposing a portion of a top surface of the lower electrode 19b. A phase change layer and an upper electrode layer are sequentially stacked, and then patterned to form a phase change pattern 23 and an upper electrode 25 so that the phase change pattern 23 and the upper electrode 25 are in contact with a top surface of the lower electrode 19b through the window 24. Kinds of the layers and methods of forming the layers which are not described in the present embodiment may be identical with the first embodiment.

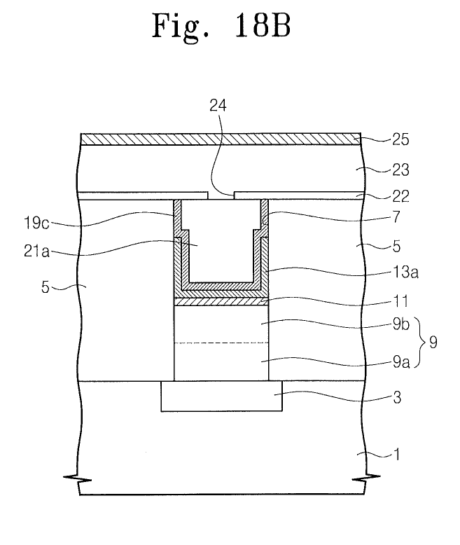

As a modified embodiment of the second embodiment, referring to FIGS. 18A and 18B, a top surface of a lower electrode 19c exposed through a window 24 may be recessed by a first depth (D). In this case, a phase change pattern 23 is in contact with the lower electrode 19c in a recess 7.

<Application Example>

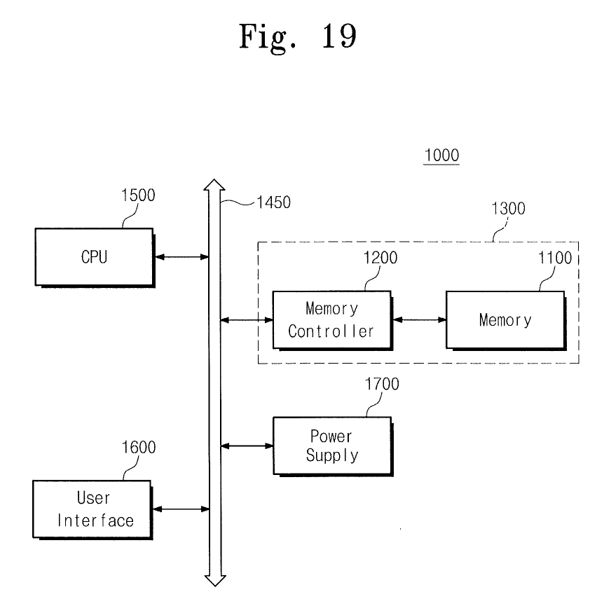

FIG. 19 is a block diagram of a memory system illustrating an application example of a phase change memory device in accordance with embodiments of the inventive concept.

Referring to FIG. 19, a memory system 1000 in accordance with the inventive concept includes a semiconductor memory device 1300 comprised of a phase change memory device 1100 (e.g., PRAM) and a memory controller 1200, a central processing unit 1500 electrically connected to a system bus 1450, a user interface 1600 and a power supply 1700.

The phase change memory device 1100 stores data provided by the user interface 1600 or processed by the central processing unit 1500 through the memory controller 1200. The phase change memory device 1100 may be comprised of a solid state disk (SSD). In this case, a write speed of the memory system 1000 may become greatly high.

Although not illustrated in the drawings, the memory system 1000 in accordance with the inventive concept may further include an application chip set, a camera image processor (CIS), a mobile DRAM or the like.

The memory system 1000 may also applied to a PDA, a portable computer, a web tablet, a wireless phone, a mobile phone, a digital music player, a memory card or all the devices which can transmit and/or receive data in a wireless environment,

Further, the phase change memory device or the memory system in accordance with the inventive concept may be mounted by various types of packages such as PoP (package on package), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP) and wafer-level processed stack package (WSP).

In a phase change memory device in accordance with the inventive concept, since a flat surface of a buffer pattern and a lower electrode are stably in contact with each other in a center of a recess, a resistance of a contact surface between the lower electrode and the buffer pattern can be minimized and thereby the phase change memory device can be operated by a small current.

A buffer pattern having an electric resistance lower than a lower electrode is located between an ohmic layer and the lower electrode, the phase change memory device may need a small program current.

Since a method of manufacturing a phase change memory device in accordance with another embodiment of the inventive concept needs one time etching process to form a recess exposing a semiconductor substrate to an insulating layer until forming a lower electrode after forming a device isolation layer, it is very economical.

The above-disclosed subject matter is to be considered illustrative, and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

1. A phase change memory device comprising:
an interlayer insulating layer including a recess exposing a semiconductor substrate;
a semiconductor layer and an ohmic layer sequentially stacked in the recess;
a buffer pattern directly contacting a top surface of the ohmic layer and having a sidewall aligned with a sidewall of the semiconductor layer;
a lower electrode directly contacting at least a portion of the buffer pattern in a center of the recess and having an upper portion higher than an uppermost portion of the buffer pattern;
a phase change pattern directly contacting only an upper portion of the lower electrode; and
an upper electrode on the phase change pattern.

2. The phase change memory device of claim 1, further comprising a spacer pattern interposed between an inner side surface of the buffer pattern and an outer side surface of the lower electrode.

3. The phase change memory device of claim 1, wherein the buffer pattern has a lower electric resistance than that of the lower electrode.

4. The phase change memory device of claim 1, further comprising a buried insulating pattern which is in contact with an inner bottom surface and an inner side surface of the lower electrode.

5. The phase change memory device of claim 1, further comprising an impurity implantation line which is formed on the semiconductor substrate and directly contacts with the semiconductor layer.

6. The phase change memory device of claim 5, wherein the impurity implantation line is doped with impurities of a first type and the semiconductor layer is doped with impurities of a second type which is opposite to the first type.

7. The phase change memory device of claim 5, wherein the semiconductor layer comprises a first semiconductor layer doped with impurities of a first type and a second semiconductor layer doped with impurities of a second type which is opposite to the first type and the first semiconductor layer and the second semiconductor layer are sequentially staked.

8. The phase change memory device of claim 7, wherein the impurity implantation line is doped with impurities of the first type.

9. The phase change memory device of claim 1, further comprising an insulating layer having a window, wherein a width of the window is narrower than an inside diameter of the recess and the phase change pattern is in contact with the lower electrode through the window.

10. The phase change memory device of claim 1, wherein an upper portion of the lower electrode is partially recessed.

11.-15. (canceled)

16. A phase change memory device comprising:
a lower electrode directly contacting at least a portion of a buffer pattern in a center of a recess and having an upper portion higher than an uppermost portion of the buffer pattern; and
a phase change pattern directly contacting only an upper portion of the lower electrode.
